(19) United States
(12) Patent Application Publication
(10) Pub. No.: US 2025/0377172 A1
(43) Pub. Date: Dec. 11, 2025

(54) FLUID HEAT EXCHANGERS WITH IMPROVED COOLING

(71) Applicant: CoolIT Systems, Inc., Calgary (CA)

(72) Inventor: Mohammad Reza Najjari, Calgary (CA)

(21) Appl. No.: 18/738,253

(22) Filed: Jun. 10, 2024

(51) Int. Cl. F28F 1/32; F28F 3/02

(52) U.S. Cl. CPC F28F 1/32; F28F 3/025; F28F 2260/02

(57) ABSTRACT

A fluid heat exchanger includes a cold plate with a base that has a first side and an opposing second side. The cold plate includes a plurality of fins extending from the second side that define a plurality of microchannels extending along a first axis. A subset of the plurality of fins defines one or more elongated recesses extending along an angularly offset second axis. A housing of the fluid heat exchanger includes a housing body defining a fluid inlet, a fluid outlet, and one or more mating protrusions configured to extend into the one or more elongated recesses such that the plurality of microchannels and the housing body form a plurality of fluid paths for circulating a heat transfer fluid along the first axis and from the fluid inlet to the fluid outlet.

### CROSS-REFERENCE TO RELATED APPLICATION(S)

This application pertains to concepts disclosed in U.S. patent application No. 60/954,987, filed on Aug. 9, 2007, and U.S. patent application Ser. No. 12/189,476, filed on Aug. 11, 2008, now U.S. Pat. No. 8,746,330. Other pertinent disclosures include U.S. patent application No. 61/512,379, filed on Jul. 27, 2011, U.S. patent application Ser. No. 13/401,618, filed on Feb. 21, 2012, now U.S. Pat. No. 9,453,691, and U.S. patent application No. 63/533,847, filed on Aug. 21, 2023. The contents of each of the foregoing patent applications is hereby incorporated by reference as fully as if reproduced herein in full, for all purposes.

### FIELD

This application and the subject matter disclosed herein (collectively referred to as the “disclosure”), generally concern components, devices, and systems for facilitating heat transfer between a solid and a liquid, and related methods. More particularly, but not exclusively, this disclosure pertains to liquid- and two-phase cooling systems that facilitate heat transfer from one or more heat-generating components to a fluid (e.g., in a liquid state, a gaseous state, or a saturated mixture of liquid and gas) passing through a fluid heat exchanger configured to facilitate mixing of a fluid passing therethrough.

### BACKGROUND INFORMATION

Many industrial processes, consumer goods, power generators, combustion chambers, communication devices, electronic components, electrical storage components (e.g., batteries), etc., and associated systems, rely on heat transfer to function as intended. For example, some rely on cooling (e.g., radio transmitters) and others rely on heating (e.g., endo-thermic chemical reactions) to maintain a temperature within a specified range between an upper threshold temperature and a lower threshold temperature.

The prior art has responded to these challenges with a number of techniques for transferring heat from one medium to another. For example, conventional air cooling uses a fan or other air-mover to draw heat away from or to convey heat to another medium. Air cooling can be supplemented with an air-cooled heat sink, e.g., often a plate of thermally conductive material having surfaces, or fins, extending from the plate to provide a larger surface area available for transferring heat to or from the air flowing over the extended surfaces.

Some heat-transfer systems use a liquid (e.g., water, glycol, polyethylene glycol, etc.) to transfer heat, as many liquids provide a relatively higher rate of convective heat transfer compared to gasses, e.g., air. In still other systems, a heat-transfer fluid can change phase from liquid to gas (or vice-versa) to absorb (or to dissipate, respectively) relatively large amounts of energy over a narrow range of temperatures. Some prior phase-change systems include a pump to increase an operating pressure of the heat-transfer fluid to urge the heat-transfer fluid through a given circulation loop, as well as to manipulate the thermodynamic state of the heat-transfer fluid to achieve a desired heat-transfer performance from the fluid. Such liquid or phase-change cooling can be accommodated by passing a coolant (e.g., as a liquid phase, or as a saturated mixture of liquid phase and gas phase) over fins extending from a surface heated by a heat source.

As used herein, the term “fluid heat exchanger” refers to any device that absorbs heat and conveys the heat to a working fluid (sometimes also referred to in the art as a “heat-transfer fluid”), regardless of whether the working fluid is in a gas phase, a liquid phase, or a saturated mixture thereof. A fluid heat exchanger can include a heat transfer interface configured to provide a thermal coupling with another device (e.g., a heat-generating or a heat-absorbing device), a heat-transfer surface configured to transfer heat to or from a heat-transfer fluid, and a material suited for conductively transferring heat from the heat-transfer interface to the heat-transfer surface, or vice-versa. Fluid heat exchangers also include other features or components, (e.g., a cold plate) and various componentry thereof or attached thereto (e.g., fluid ports and/or conduits, brackets, housings, fastening/latching features, pumps, fans, etc.). Fluid heat exchangers include active units (e.g., a heat exchanger that incorporates a fan or a pump to urge a heat-transfer fluid through or over a heat-transfer surface) or passive units (e.g., a heat exchanger that relies on natural convection or an external pump or fan to cause a heat-transfer fluid to pass through or over a heat-transfer surface).

### SUMMARY

Presently disclosed principles improve performance over prior fluid heat-exchangers and related systems by providing features that manipulate a flow of a working fluid that improve convective heat transfer as the working fluid passes through a fluid heat-exchanger, and more particularly but not exclusively, as the working fluid passes through one or more microchannels defined by the fluid heat-exchanger. For example, disclosed fluid heat-exchangers can have a base defining an upper surface and a plurality of walls, or fins, extending from the upper surface. For example, the walls, or fins, extend away from the upper surface from a proximal edge to a distal edge. The proximal edge is contiguous with, and in some cases, continuous with, the base, e.g., the supper surface of the base, and the distal edge is spaced apart from the upper surface of the base. Adjacent pairs of walls define a microchannel therebetween.

As used herein, the term “cold plate” means a component having a base plate defining a first major surface, a second major surface positioned opposite the first major surface, and a plurality of extended heat-transfer surfaces thermally coupled with the second major surface. In some embodiments, such extended heat-transfer surfaces are defined by a plurality of walls extending from the second major surface. In other embodiments, such extended heat transfer surfaces are defined by a heat-exchanger core thermally coupled with the base plate and the heat-exchanger core is configured to permit a working fluid to pass therethrough to convectively transfer heat to or from the heat-transfer surfaces of the heat-exchanger core, which in turn conveys such heat to or from the base plate.

As the working fluid passes through the microchannels or other heat-exchanger core, heat can transfer convectively to the walls from the fluid, or vice-versa, depending on whether the working fluid is warmer or cooler than the walls. A rate of heat transfer between the working fluid and the wall at any location along the wall depends on the temperature gradient between the fluid and the wall at that location. As the working fluid penetrates more deeply lengthwise along the microchannel, convective heat transfer rates tend to diminish because a temperature of the working fluid adjacent the walls (or fins) approaches the wall temperature.

In some embodiments, the distal edge of each fin among a plurality of the fins defines a plurality of recessed notches. One or more of the plurality of recessed notches defined by each fin can align with a corresponding one or more notches defined by an adjacent fin. In some embodiments, a selected plurality of fins from among the plurality of fins have one or more notches so aligned with each other that they define a recessed groove extending transversely relative to the selected plurality of fins.

Disclosed fluid heat exchangers also include a housing positioned overtop the plurality of fins and microchannels. An outer perimeter of the base plate and an outer perimeter of the housing can be complementarily configured relative to each other such that they can be sealably coupled together with each other to inhibit or to prevent leakage of a working fluid from the heat exchanger as the working fluid passes therethrough. The housing can define an underside surface configured to be positioned overtop the plurality of fins. The underside surface can have a complementary contour corresponding with a contour defined by the distal edges of the plurality of fins. In some embodiments, the underside surface has a complementary contour corresponding to the distal edges of the fins and the notches defined thereby. In still further embodiments, the underside surface has a complementary contour corresponding to the distal edges of the fins and the one or more transverse grooves defined by aligned notches of adjacent fins, allowing an undulating underside surface defined by the housing to mate with the corresponding undulating distal edges of the plurality of fins. In some instances, such mating (e.g., meshing, like complementary gears) between the housing and the distal edges of the fins allows housing to urge against the fins while eliminating the need for an intervening gasket, plate or other component conventionally used to inhibit or to prevent a working fluid from leaking out of or bypassing the microchannels.

Disclosed concepts, including the mating engagement between the undulating underside of the housing and the undulating distal edges of the fins encourage mixing, circulation and recirculation of the working fluid passing through the microchannels. Such mixing, circulation or recirculation tends to sweep fluid particles at or near the wall (which tend to have a temperature approaching that of the wall) away from the wall (referred to in the art as “advection”), replacing them with fluid particles having a different (e.g., a warmer or a cooler) temperature. Such advection thus introduces or maintains a relatively larger temperature gradient between the working fluid and the wall surface in regions close to the wall, thus providing higher rates of heat transfer near the wall than otherwise would exist absent such advection provided by the complementary contours of the housing underside and the distal fin edges.

As noted, by embodying disclosed principles, fluid heat exchangers can incorporate cold plates with variable fin heights and housings with complementary contours, which can introduce turbulence that mixes the fluid as it circulates through the fluid microchannels. The mixing of the fluid can facilitate thinning of the thermal boundary layer in the circulating fluid adjacent to the cold plate, which can provide a higher heat transfer efficiency and/or rate of heat conduction. Disclosed embodiments can thus be implemented to improve the cooling of electronic components or other heat sources in contact with cold plates of fluid heat exchangers.

According to a first aspect, a fluid heat exchanger includes a cold plate and a housing. The cold plate includes a base plate having a heat transfer interface defined by a first side and configured to contact an electronic component, and a second side opposite the first side. The cold plate also includes a plurality of fins extending from the second side. The plurality of fins and the second side of the base plate define a plurality of microchannels extending along a first axis. At least a subset of fins of the plurality of fins defines one or more aligned notches that, together, define one or more elongated recesses extending along a second axis that is angularly offset from the first axis. The housing includes a housing body that defines a fluid inlet, a fluid outlet, and a contoured underside defining one or more ridges, bosses, or other protrusions (hereinafter referred to generally as a “mating protrusion”). One or more mating protrusions is configured to extend into the one or more elongated recesses. The underside of the housing closes off an uppermost extent of the microchannels to inhibit or to prevent leakage or bypass of a working fluid flowing within the microchannels. The plurality of microchannels and the housing body form a plurality of fluid paths for passing a heat transfer fluid along the first axis and from the fluid inlet to the fluid outlet or vice-versa.

In some embodiments, the fluid heat exchanger has an intermediate plate that intervenes between the housing body and the cold plate. In other embodiments, the fluid heat exchanger lacks such an intermediate plate that intervenes between the housing body and the cold plate.

In some embodiments, the subset of fins of the cold plate define a central elongated recess. In some implementations, the housing body comprises one or more partial (or truncated) protrusions configured to partially extend into the central elongated recess when the one or more mating protrusions extend into the one or more elongated recesses.

In some embodiments, each of the one or more elongated recesses is defined by aligning a recessed notch defined by each in a plurality of neighboring fins with the other recessed notches defined by the plurality of neighboring fins. Such an elongated recess thus has a discontinuous surface defined by the distal edges of the plurality of notched fins. In some embodiments, the discontinuous surface of one or more of the elongated recesses defines a first discontinuous wall, a second discontinuous wall, and a discontinuous base, e.g., extending from the first discontinuous wall to the second discontinuous wall. The first discontinuous wall, the second discontinuous wall, and the discontinuous base can be defined by the subset of fins of the plurality of fins. The first discontinuous wall can be non-parallel to the second discontinuous wall.

According to another aspect, a fluid heat exchanger includes a cold plate and a housing. The cold plate includes a base plate having a heat transfer interface defined by a first side and configured to contact an electronic component, and a second side opposite the first side. The cold plate also includes a plurality of fins extending from the second side. The plurality of fins and the second side of the heat transfer interface define a plurality of microchannels extending along a first axis. At least a subset of fins of the plurality of fins defines a plurality of elongated recesses extending along a second axis that is angularly offset from the first axis. The plurality of elongated recesses comprises a central elongated recess. The housing is configured to connect to the cold plate includes one or more mating protrusions configured to extend into at least some of the plurality of elongated recesses when the housing connects to the cold plate such that the plurality of microchannels and the housing form a plurality of fluid paths for circulating a heat transfer fluid along the first axis. The housing also includes a housing body defining a central cavity arranged over the central elongated recess when the housing connects to the cold plate.

In some embodiments, the housing omits a mating protrusion configured to extend into the central elongated recess when the housing connects to the cold plate.

In some embodiments, the housing comprises one or more partial protrusions configured to partially extend into the central elongated recess when the housing connects to the cold plate.

In some embodiments, the housing body defines a fluid inlet, a fluid outlet, and the one or more mating protrusions. In some implementations, the fluid heat exchanger omits an intermediate plate that intervenes between the housing body and the cold plate.

In some embodiments, each of the plurality of elongated recesses is defined by a first discontinuous wall, a second discontinuous wall, and a discontinuous base. The first discontinuous wall, the second discontinuous wall, and the discontinuous base can be defined by the subset of fins of the plurality of fins. The first discontinuous wall can be non-parallel to the second discontinuous wall.

According to another aspect, a cold plate for a fluid heat exchanger includes a base plate having a heat transfer interface defined by a first side and configured to contact an electronic component, and a second side opposite the first side. The cold plate also includes a plurality of fins extending from the second side. The plurality of fins and the second side of the heat transfer interface define a plurality of microchannels extending along a first axis. At least a subset of fins of the plurality of fins defines one or more elongated recesses extending along a second axis that is angularly offset from the first axis. Each of the one or more elongated recesses is defined by a first discontinuous wall, a second discontinuous wall, and a discontinuous base, where the first discontinuous wall, the second discontinuous wall, and the discontinuous base are defined by the subset of fins of the plurality of fins. For each elongated recess, the first discontinuous wall is non-parallel to the second discontinuous wall.

In some embodiments, for each of the one or more elongated recesses, the first discontinuous wall and the second discontinuous wall converge toward the discontinuous base.

In some embodiments, the one or more elongated recesses comprise a plurality of elongated recesses. In some implementations, at least two elongated recesses of the plurality of elongated recesses comprise different discontinuous base widths. In some instances, at least two sets of adjacent elongated recesses of the plurality of elongated recesses comprise different distances between adjacent discontinuous bases. In some examples, the subset of fins of the plurality of fins defines a plurality of bridges between adjacent elongated recesses of the plurality of elongated recesses. In some embodiments, at least two of the plurality of bridges comprise different widths. In some implementations, a distance from one bridge of the plurality of bridges to the second side of the heat transfer interface is different from another distance from another bridge of the plurality of bridges to the second side of the heat transfer interface. In some instances, at least two elongated recesses of the plurality of elongated recesses comprise different distances from the second side of the heat transfer interface to the discontinuous base.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 schematically illustrates a closed liquid-cooling loop.

FIG. 2 illustrates an isometric view of a fluid heat exchanger including a housing and a cold plate.

FIG. 3 illustrates an isometric view of a cold plate suitable for a fluid heat exchanger.

FIG. 4 illustrates side elevation view of a portion of a cold plate.

FIG. 5 illustrates a front perspective view of a cross-section of the cold plate shown in FIG. 3 taken along line X-X.

FIG. 6 illustrates perspective view from below a housing suitable for a fluid heat exchanger.

FIG. 7 illustrates a perspective view from in front of a cross-section of the fluid heat exchanger in FIG. 2 taken along line Y-Y.

FIG. 8 illustrates a side elevation view of the cross-section shown in FIG. 7.

FIG. 9 illustrates a front elevation view of the cross-section shown in FIG. 5.

### DETAILED DESCRIPTION

The following describes various principles pertaining to fluid heat exchangers and related components and/or methods. That said, descriptions herein of specific apparatus configurations and combinations of method acts are but particular examples of the variety of contemplated embodiments, chosen as being convenient to illustrate disclosed principles. One or more of the disclosed principles can be incorporated in various other embodiments to achieve any of a variety of corresponding system characteristics.

Thus, embodiments of disclosed principles having attributes that are different from those specific embodiments discussed herein can embody one or more presently disclosed principles, and can be used in applications not described herein in detail. Accordingly, such alternative embodiments also fall within the scope of this disclosure.

### I. Overview

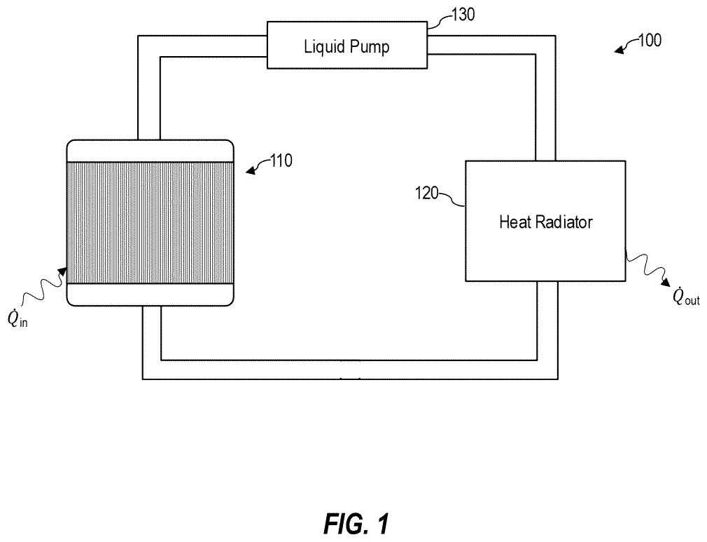

FIG. 1 illustrates various components of a heat-transfer system embodied as a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

As noted above, fluid heat exchangers can be used to cool a variety of electronic components, such as, by way of non-limiting example, central processing units, graphics processing units, neural processing units, holographic processing units, power supply units/components, memory (e.g., random access memory, solid state or hard disk drives, etc.), chipsets, network interface components, sound components, and/or others. Conventional fluid heat exchangers have included a cold plate with fins extending therefrom that define fluid microchannels with uniform height for facilitating fluid flow to achieve cooling of an electronic component in contact with the cold plate. However, the constant fin height of conventional fluid microchannels often fails to address the thermal boundary layer in the fluid adjacent to the cold plate fins, which can act as an insulating layer and can reduce the rate of heat transfer from the walls defining the microchannel.

A disclosed cold plate for a fluid heat exchanger has a plurality of fins that define one or more elongated recesses that extend in a direction transverse to a longitudinal axis of the microchannels. The distal edge of each fin can define a recessed notch that contributes to defining an elongated recess. Stated differently, the distal fin edges can have varying height (e.g., distance from an upper surface of the base plate) along a length of the fin (e.g., along a spanwise segment of the base plate that defines the fin), and an elongated recess can be defined by aligning corresponding recessed regions of the edges of a plurality of adjacent fins. In one example, an elongated recess can have a generally trapezoidal cross-sectional shape characterized by two sloping walls that converge toward each other and a base. The sloping walls and the base can be defined by the profile of edges of multiple adjacent fins (e.g., by aligned recesses defined by the edges of the multiple adjacent fins) extending from the base plate.

The elongated recesses of a cold plate can be configured to receive correspondingly shaped protrusions, or ridges, defined by an underside of a housing of a fluid heat exchanger. Each protrusion can fill a corresponding portion of one or more elongated recesses and can promote “turbulence” or mixing of a working fluid passing through the microchannels between the fins that define the elongated recesses. For instance, continuing with the above example where the elongated recesses have a trapezoidal shape, the mating protrusions may fill the trapezoidal recesses such that fluid circulating through the underlying microchannels is forced to pass below the reduced-height bases of the trapezoidal recesses, which can cause a jet effect that disrupts the thermal boundary layer and promotes mixing (e.g., by introducing circulation or recirculation regions) of the fluid within the microchannel. Such mixing of the fluid can disrupt and reduce a thickness of the thermal boundary layer, which can increase convective heat transfer rates between the fluid and the fins.

In some instances, the protrusions are defined by the housing (e.g., an underside portion of the housing that defines the fluid ports, such as inlet and outlet ports), which can reduce device complexity and/or improve manufacturing efficiency. In other embodiments, the protrusions can be defined by a manifold plate positioned between the fins and the housing (e.g., analogous to the plate 240 in U.S. Pat. No. 8,746,330). In some instances, the housing body defines a central cavity (e.g., a fluid inlet cavity, or other portion of an inlet manifold) positioned over a selected one or more among a plurality of elongated recesses, for example, a selected central elongated recess, defined by a plurality of fins of the cold plate when the housing is connected to the cold plate. The housing body can further define one or more partial protrusions that only partially extend into the central elongated recess (e.g., along the sides of the central cavity). The partial protrusions may act as turbulence promoters for circulating fluid as it approaches and passes the central elongated recess, which can further contribute to fluid mixing which, in turn, can disrupt the thermal boundary layer of flowing fluid.

In some instances, the elongated recesses defined by fins of a cold plate can have different shape characteristics. For instance, continuing with the above example where the elongated recesses have a trapezoidal shape, different elongated recesses can have different base widths or wall distances or slopes. Furthermore, different bases of different elongated recesses can have different heights relative to the heat transfer surface of the cold plate. Also, the height and/or width of bridges (defined by fin edges) that intervene between adjacent elongated recesses can be different for different pairs of adjacent elongated recesses. Other cross-sectional shapes (e.g., square, rectangular, triangular, rounded, parabolic, hyperbolic, or any other arbitrary shape) of elongated recesses can be defined by fins of a cold plate and such other cross-sectional shapes are within the scope of the present disclosure.

### II. Fluid Heat Exchangers and Components Thereof

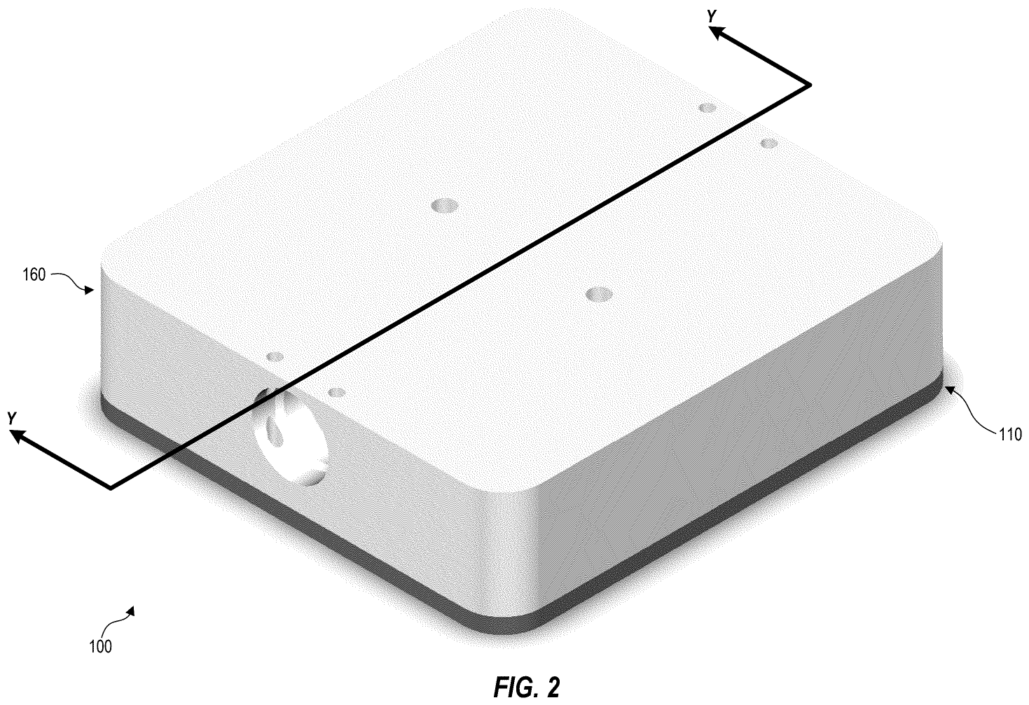

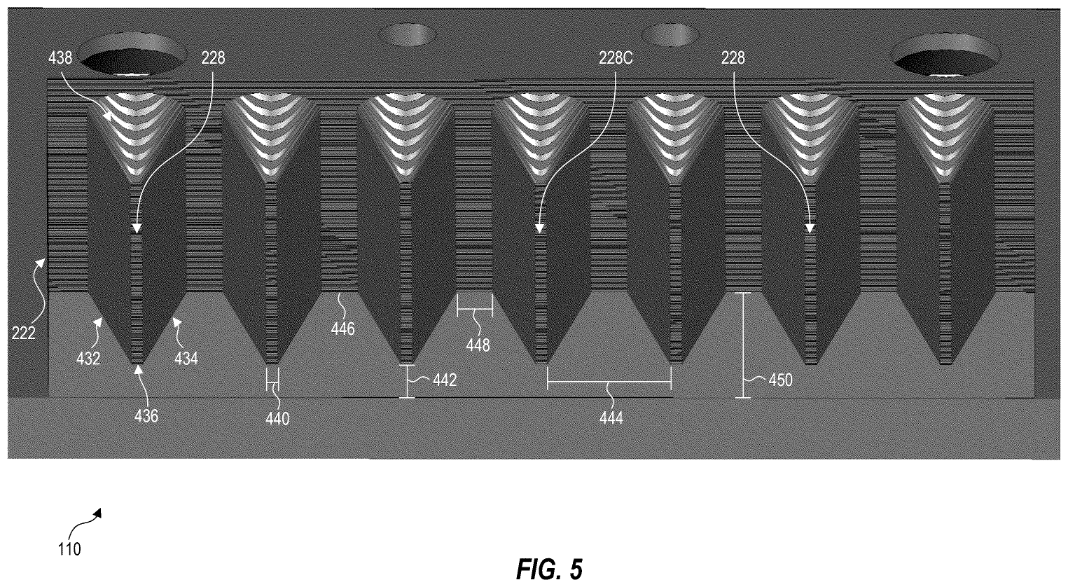

FIG. 2 illustrates an isometric view of a fluid heat exchanger 100, in accordance with the disclosed subject matter. The fluid heat exchanger 100 shown in FIG. 2 includes a cold plate 110 and a housing 160 that is connected (or configured to connect) to the cold plate 110. The housing 160 can connect to the cold plate 110 in various ways, such as via one or more fasteners configured to engage with one or more mounting holes (e.g., mounting holes 212 and 562 shown in FIGS. 2 and 5, respectively). Applicant's U.S. Pat. No. 8,746,330 and co-pending U.S. patent application No. 63/533,847, filed Aug. 21, 2023, the contents of which are hereby incorporated by reference the same extent as if reproduced herein in full, for all purposes, also discloses suitable approaches for assembling a housing and a cold plate with each other.

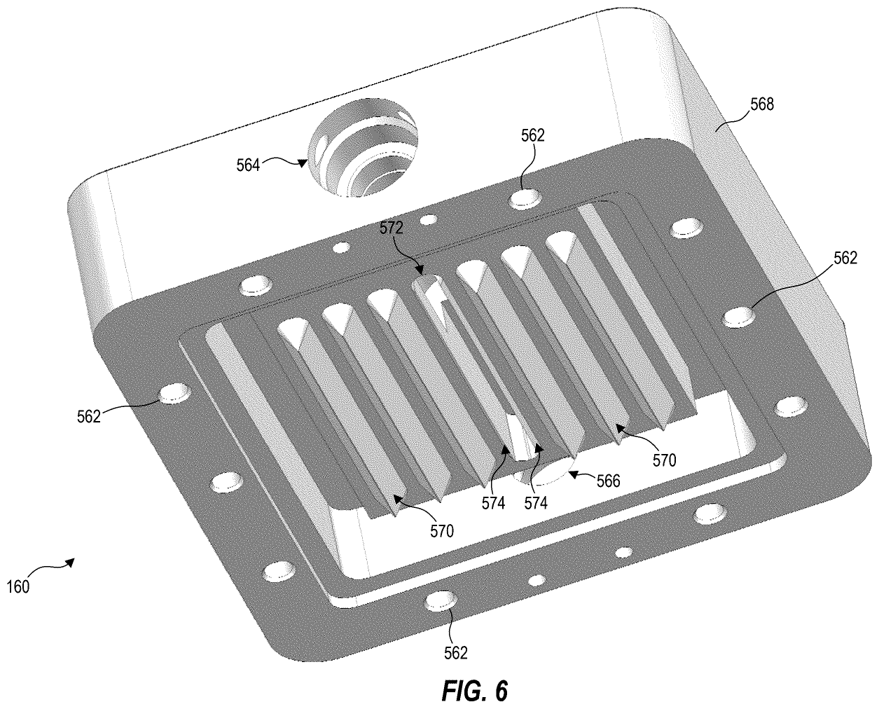

The cold plate 110 can be configured to be retained in contact with an electronic component (or other heat source) to facilitate cooling of the electronic component. The cold plate 110 and the housing 160, when connected together, can define various fluid paths or conduits through which a fluid can flow (e.g., via an integrated pump or a separate pump, as in FIG. 1) to allow the cold plate 110 to convey heat from the electronic component to the fluid. The fluid can enter and exit the fluid heat exchanger 100 via tubing connected to fluid ports of the fluid heat exchanger 100 (see fluid inlet 564 and fluid outlet 566 shown in FIG. 6) and can be cooled via cooling loop components (e.g., a radiator, one or more fans, etc.).

The cold plate 110 and/or the housing 160 can be formed from materials with high thermal conductivity to efficiently transfer heat from the component being cooled to the circulating fluid, such as, for example, aluminum, copper, stainless steel, composites, vapor chambers, and/or others.

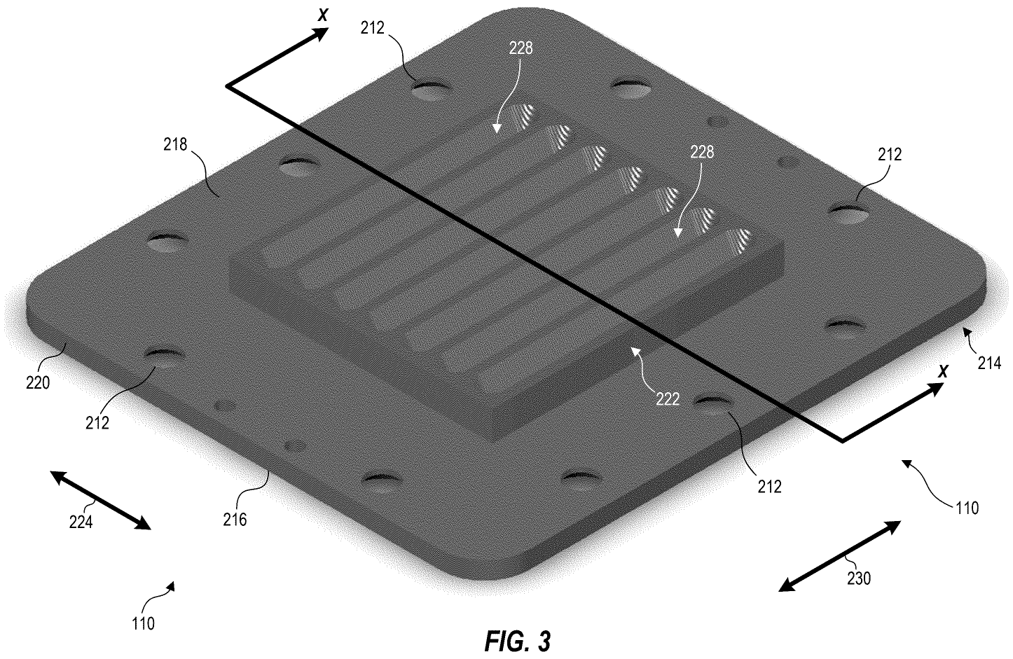

The fluid paths or conduits of the fluid heat exchanger 100 can be formed by various components or features of the cold plate 110 and the housing 160. FIG. 3 illustrates an isometric view of the cold plate 110 of the fluid heat exchanger 100. FIG. 3 illustrates optional mounting holes 212 through the cold plate 110, which can receive one or more fasteners to facilitate connection of the cold plate 110 to the housing 160, as mentioned above. The cold plate 110, as illustrated in FIG. 3, includes a base plate 214 with a first side 216 defining a heat-transfer interface for contacting an electronic component (with or without an intervening thermal interface material) to facilitate cooling of the electronic component. The base plate 214 also includes a second side 218 (e.g., an upper side) that is opposite to the first side 216 (e.g., a lower side), with an outer edge 220 intervening between the first side 216 and the second side 218.

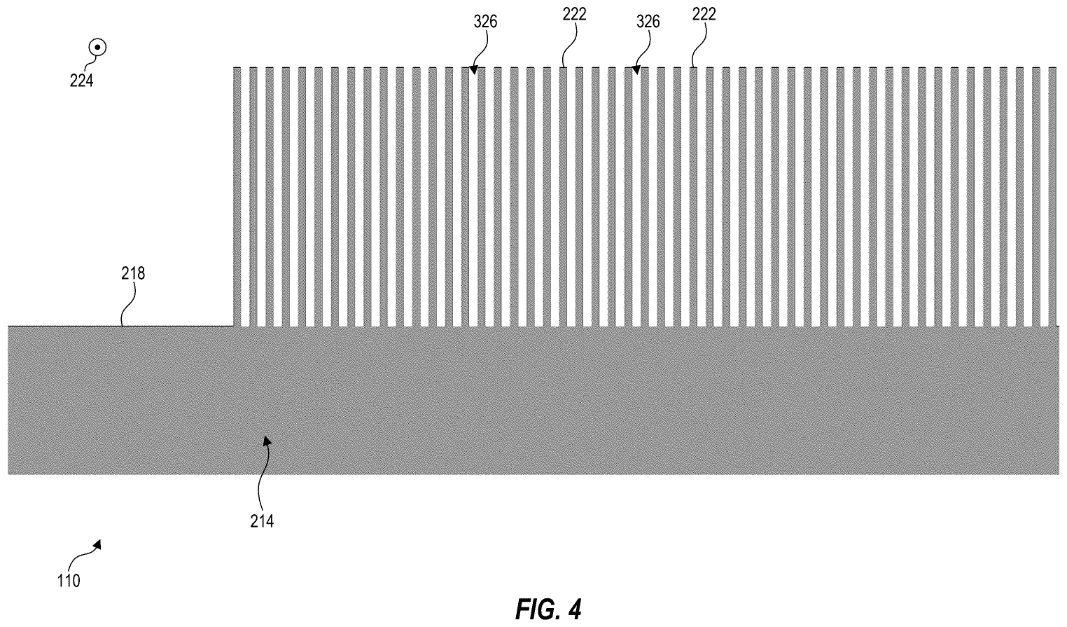

In FIG. 3, the cold plate 110 includes a heat exchanger core having a plurality of fins 222 extending outward (or upward) from a major surface defined by the second side 218. Together with the second side 218 of the base plate 214, the fins 222 form microchannels that extend along an axis (e.g., an axis parallel to the axis 224) associated with the cold plate 110. FIG. 4 provides a \ side view of the cold plate 110 and illustrates the microchannels 326 formed by the fins 222 (acting as microchannel walls) and the second side 218 of the base plate 214 (acting as the microchannel floor for each microchannel), with the microchannels 326 extending along the axis (e.g., an axis parallel to the axis 224) (which is illustrated in FIG. 4 as extending into and out of the drawing sheet).

Reference is again directed to FIG. 3, which illustrates that a selected plurality of the fins 222 define a plurality of elongated recesses 228. The elongated recesses 228 can be formed by recessed notches defined by the edges (e.g., top, or distal, edges) of adjacent fins 222 of the cold plate 110, with the shape of each particular elongated recess 228 being defined by variation in the height of the edges of the adjacent fins 222 that form the particular elongated recess.

As will be described in more detail hereinafter, the elongated recesses 228 can be configured to receive corresponding protrusions associated with the housing 160 when the housing 160 is connected to the cold plate 110. When connected, the mating protrusions of the housing 160 can overlie the microchannels 326 and, together with an underside of the housing, close off an upper extent of the microchannels 326 formed by the fins 222 and the second side 218 of the base plate 214, defining enclosed fluid paths (e.g., extending along the axis 224) through which a fluid (e.g., a coolant or heat transfer fluid) can flow to facilitate cooling of an electronic component in contact with the cold plate 110. A profile of each mating protrusion, whether defined by the housing 160 or a manifold plate, can follow the variations in the height of the edges of the fins 222 that define the elongated recesses 228, allowing the mating protrusions to sit within a spanwise segment of each microchannel underlying the mating protrusions and to interfere with a flow of working fluid through the microchannel. Such mating protrusions act as turbulence promoters for the fluid paths defined by the affected microchannels. The mating protrusions of the housing 160 tend to cause a local speed of the working fluid passing through the microchannel to accelerate in the vicinity of the mating protrusion, thus contributing to reduced thickness of the thermal boundary layers near the mating protrusions, which in turn can improve cooling performance of the fluid heat exchanger 100 relative to conventional devices.

In FIG. 3, the elongated recesses 228 have longitudinal axes that are angularly offset from the axis 224. For example, FIG. 3 depicts the elongated recesses 228 as extending parallel to an axis 230 that is perpendicular to the axis 224. Other angular offsets between the longitudinal axes of one or more elongated recesses 228 and the axis 224 along which the microchannels 326 extend are within the scope of the present disclosure. In some instances, different elongated recesses 228 have longitudinal axes that have different angular offsets from the axis 224. As another example, an elongated recess 228 can have a longitudinal axis parallel to the axis 224 along which the microchannels 326 extend. Although shown as having similar or equal lengths, the elongated recesses can have any selected length, with some in a plurality of elongated recesses having relatively shorter lengths and others in the plurality of elongated recess having relatively longer lengths.

FIG. 5 shows additional details of the elongated recesses 228 described hereinabove. In FIG. 5, an elongated recess 228 can be defined by one or more discontinuous walls formed from the top edges of adjacent fins 222. For instance, FIG. 5 illustrates a first discontinuous wall 432 and a second discontinuous wall 434 that define the sidewalls of one of the elongated recess 228. FIG. 5 also illustrates a discontinuous base 436 that defines the floor of the elongated recess 228 (reference labeling of the discontinuous walls and discontinuous base of other elongated recesses 228 are omitted in FIG. 5 for clarity). In the example shown in FIG. 5, the first discontinuous wall 432 and the second discontinuous wall 434 are non-parallel, with slopes that converge toward the discontinuous base 436, giving the example elongated recesses 228 a generally trapezoidal microchannel shape. Such “discontinuous walls” are defined by edges of a plurality of neighboring fins aligned with each other to define the elongated recesses.

The elongated recesses 228 shown in FIG. 5 also include recess ends 438, which can be regions where the heights of adjacent edges of adjacent fins 222 that form the elongated recess 228 have different heights. For instance, the heights of the edges of the fins 222 at a recess end 438 can increase fin by fin until the end of the elongated recess 228 is reached.

One will appreciate, in view of the present disclosure, that different arrangements, shapes, and/or quantities of discontinuous walls, discontinuous bases, and/or recess ends may be used to form an elongated recess of a cold plate of a fluid heat exchanger. For instance, an elongated recess can comprise a rectangular microchannel or square microchannel shape (e.g., with sharp vertical walls) with (or without) recess ends characterized by fins with increasing edge heights. As another example, an elongated recess can comprise a half-pipe or other arcuate microchannel shape with recess ends characterized by fins with increasing edge heights. In some instances, an elongated recess can omit recess ends as described above and can instead abruptly terminate at a full-height fin of the cold plate or can extend to the end of the arrangement of fins of the cold plate (e.g., with the end fin of the cold plate having reduced height to contribute to formation of the elongated recess).

Furthermore, although the foregoing examples have focused, in at least some respects, on elongated recesses formed via adjacent fins of a cold plate, recesses formed via adjacent fins of a cold plate need not be elongated in nature and can instead be radially symmetric or non-axial or irregular. One will appreciate, in view of the present disclosure, that different recesses formed by adjacent fins of a single cold plate can have different shape and/or symmetry characteristics.

FIG. 5 illustrates an example in which fins 222 of the cold plate 110 form seven elongated recesses 228, with one of them being a central elongated recess 228C. However, fins 222 of a cold plate 110 can define any quantity of elongated recesses 228 and can include or omit a central elongated recess.

Where multiple elongated recesses 228 are defined by fins 222 of the cold plate 110, different elongated recesses, or the discontinuous walls and/or bases that form the different elongated recesses 228, can have different characteristics, which can enable tailoring of mixing characteristics (and, resultingly, cooling characteristics) at different parts of the cold plate 110. In one example, different elongated recesses 228 can have different widths 440 of their discontinuous bases 436. As another example, different elongated recesses 228 can have different distances 442 from their discontinuous base 436 to the second side 218 of the base plate 214. As yet another example, different sets of adjacent elongated recesses 228 can have different distances 444 between their adjacent discontinuous bases 436.

FIG. 5 illustrates that fins 222 of the cold plate 110 can define bridges 446 between adjacent elongated recesses 228 (or between adjacent discontinuous walls of adjacent elongated recesses 228). In some instances, different bridges 446 between different sets of adjacent elongated recesses 228 can have different widths 448. In some implementations, different distances 450 can exist between different bridges 446 and the second side 218 of the base plate 214.

The relative sizes and shapes of the elongated recesses 228 formed by the fins 222 of the cold plate 110 shown in FIG. 5 have been found to promote fluid mixing during coolant circulation in a manner that achieves beneficial cooling characteristics for electronic components in contact with the cold plate 110. In the example shown in FIG. 5, the ratio of the width 440 of a discontinuous base 436 to the distance 442 of a discontinuous base 436 to the second side 218 of the base plate 214 is about 3:10 (e.g., within a range of about 1:10 to about 20:1, or within a range of about 1:5 to about 2:5). The ratio of the width 440 of a discontinuous base 436 to the distance 444 between adjacent discontinuous bases 436 is about 1:10 (e.g., within a range of about 1:20 to about 20:1, or within a range of about 1:20 to about 1:1). The ratio of the width 440 of a discontinuous base 436 to the width 448 of a bridge 446 is about 3:10 (e.g., within a range of about 1:20 to about 20:1, or within a range of about 1:5 to about 2:5). The ratio of the width 440 of a discontinuous base 436 to the distance 450 between adjacent bridges 446 is about 1:10 (e.g., within a range of about 1:20 to about 20:1, or within a range of about 1:20 to about 1:5). The ratio of the distance 442 to the distance 444 is about 3:10 (e.g., within a range of about 25:100 to about 3:1, or within a range of about 1:5 to about 2:5). The ratio of the distance 442 to the width 448 is about 95:100 (e.g., within a range of about 25:100 to about 6:1, or within a range of about 9:10 to about 1:1). The ratio of the distance 442 to the distance 450 is about 3:10 (e.g., within a range of about 1:10 to about 4:5, or within a range of about 1:5 to about 2:5). The ratio of the width 448 to the distance 444 is about 3:10 (e.g., within a range of about 1:10 to about 1:1, or within a range of about 1:5 to about 2:5). The ratio of the distance 450 to the distance 444 is about 9:10 (e.g., within a range of about 1:10 to about 6:1, or within a range of about 4:5 to about 1:5). The ratio of the width 448 to the distance 450 is about 3:10 (e.g., within a range of about 1:10 to about 6:1, or within a range of about 1:5 to about 2:5). One will appreciate that the relative sizes of the various components described hereinabove are provided by way of example only and can be varied in different implementations within the scope of the present disclosure.

FIG. 6 illustrates the mounting holes 562 of the housing 160, which can receive one or more fasteners to facilitate connection of the housing 160 to the cold plate 110, as mentioned above. The housing 160, as illustrated in FIG. 6, includes a housing body 568 that defines various features, including a fluid inlet 564, a fluid outlet 566, and mating protrusions 570. The fluid inlet 564 and the fluid outlet 566 can receive and/or secure tubing of a cooling loop to facilitate circulation of coolant through fluid paths formed by the housing 160 and the cold plate 110 when connected together. One will appreciate that the characterization of the fluid ports of the housing 160 as inlets or outlets is arbitrary and could be reversed in some implementations. For example, in some embodiments, a working fluid can enter the port referred to herein as an outlet port and exhaust from the port referred herein as an inlet port. In other words, a working fluid can flow through a heat exchanger in a direction opposite to that described in connection with certain embodiments.

As indicated above, the mating protrusions 570 can be configured to extend into the elongated recesses 228 defined by fins 222 of the cold plate 110 when the housing 160 is connected to the cold plate 110. Accordingly, the mating protrusions 570 can comprise shapes that at least partially correspond to the shapes of the elongated recesses 228. In the example shown in FIG. 6, the mating protrusions 570 are embodied with a generally elongated trapezoidal shape with rounded ends to correspond to the elongated recesses 228 defined by the first discontinuous walls 432, second discontinuous walls 434, discontinuous bases 436, and the recess ends 438 formed by the edges of fins 222 of the cold plate 110.

In the example shown in FIG. 6, the housing body 568 also defines a central cavity 572, which can be open to or arranged over the central elongated recess 228C when the housing 160 is connected to the cold plate 110. The central cavity 572 is open to the fluid inlet 564, enabling fluid to travel through the fluid inlet 564 and the central cavity 572 toward the central elongated recess 228C, or vice-versa. FIG. 6 also illustrates that the housing body 568 can define partial protrusions 574 positioned about the central cavity 572. The partial protrusions 574 can be configured to partially extend into the central elongated recess 228C when the cold plate 110 is connected to the housing 160.

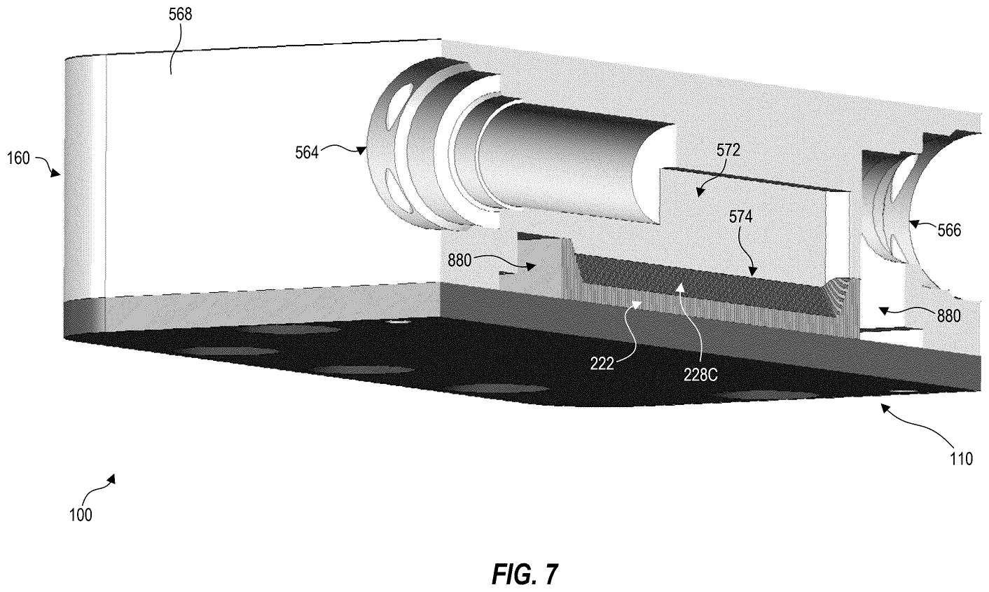

FIG. 7 illustrates a front perspective cross-sectional view of the fluid heat exchanger 100 with the cold plate 110 connected to the housing 160. FIG. 7 illustrates the central cavity 572 of the housing 160 arranged over the central elongated recess 228C of the cold plate 110. FIG. 7 also illustrates one of the partial protrusions 574 extending partially into the central elongated recess 228C. Under the configuration shown in FIG. 7, fluid may enter the fluid inlet 564 and reach the central cavity 572, where it is directed downward past the partial protrusions 574 toward the central elongated recess 228C defined by fins 222 of the cold plate 110. The partial protrusions 574 can operate as turbulence promoters for fluid approaching or entering the central elongated recess 228C from the central cavity 572, which can contribute to improved heat transfer efficiency of the fluid heat exchanger 100. In some instances, the partial protrusions 574 comprise a shape that conforms to the discontinuous walls of the central elongated recess 228C but that does not extend coextensive with the discontinuous walls toward the discontinuous base of the central elongated recess 228C. In the example shown, the partial protrusions 574 descend to a depth of less than 40% (or less than 30%) of the overall depth of the central elongated recess 228C, though other relative depths are within the scope of the present disclosure.

In some instances, the housing 160 omits any mating or partial protrusion for extending into the central elongated recess 228C when the housing 160 is connected to the cold plate 110 (or, as noted above, the cold plate 110 may omit a central elongated recess 228C). Furthermore, although various components of the housing 160 are described above as being defined or formed by the housing body 568 itself (e.g., the fluid inlet 564, the fluid outlet 566, the mating protrusions 570, the central cavity 572, the partial protrusions 574), one or more of these components may be defined (at least in part) by additional materials and/or components that are connected to the housing body 568. For instance, in another embodiment one or more intermediate plates or gaskets (as in U.S. Pat. No. 8,746,330) can intervene between the housing body 568 and the cold plate 110 may form one or more of the mating protrusions 570. In some instances, integrally forming one or more of the fluid inlet 564, the fluid outlet 566, the mating protrusions 570, the central cavity 572, and/or the partial protrusions 574 with the housing body 568 can reduce manufacturing complexity or costs and/or can reduce device error rates.

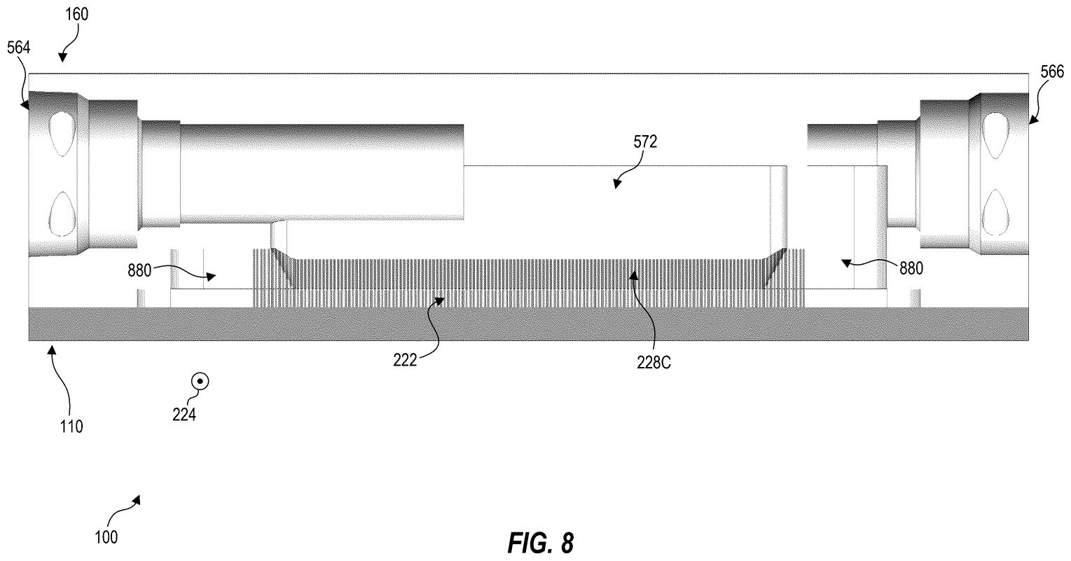

When the housing 160 is connected to the cold plate 110, the mating protrusions 570 of the housing 160 and the microchannels 326 of the cold plate 110 can form fluid paths through which a fluid can circulate to facilitate cooling of an electronic component in contact with the cold plate. FIG. 8 illustrates a side cross-sectional view of the fluid heat exchanger 100 with the housing 160 connected to the cold plate 110. FIG. 8 shows a side view of fluid paths formed by the mating protrusions 570 of the housing 160 and the microchannels 326 of the cold plate 110 (reference labels for the mating protrusions 570 and the microchannels 326 are omitted from FIG. 8 for the sake of clarity of the Figures). The fluid paths may be open to the central elongated recess 228C, which can allow fluid directed downward from the central cavity 572 to enter the fluid paths to circulate among the fins 222 of the cold plate 110 to achieve cooling of an electronic component in contact with the cold plate 110. While experiencing mixing caused by the mating protrusions 570, the fluid may circulate through the fluid paths along the axis 224.

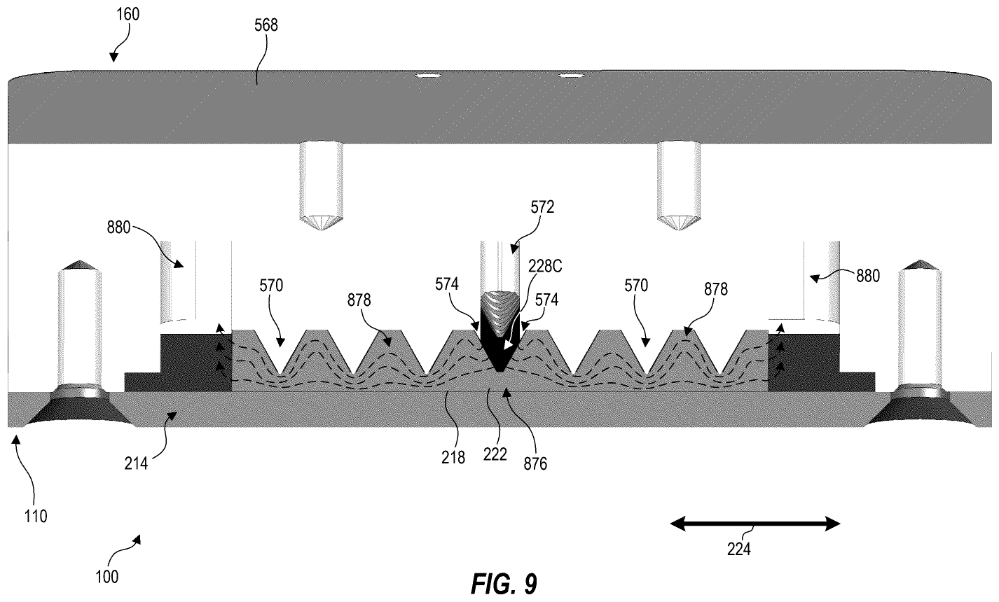

FIG. 9 illustrates a front cross-sectional view of the fluid heat exchanger 100 with the cold plate 110 connected to the housing 160. FIG. 9 illustrates one of the fluid paths 876 formed by (i) mating protrusions 570 of the housing 160, (ii) adjacent fins 222 of the cold plate 110 (one of which is cut out of view in the cross-sectional view shown in FIG. 9), and (iii) the second side 218 of the base plate 214 of the cold plate 110. In the example shown in FIG. 9, the fluid path 876 is open to the central elongated recess 228C, which allows fluid from the fluid inlet 564 and the central cavity 572 to pass through the central elongated recess 228C to enter the fluid path 876. FIG. 9 illustrates flow lines 878 (dashed arrows) that conceptually depict example circulation paths of fluid entering the fluid path 876 from the central cavity 572 via the central elongated recess 228C and passing through the fluid path 876. The flow lines 878 shown in FIG. 9 indicate that partial protrusions 574 and the mating protrusions 570 of the housing 160 can promote mixing of the fluid while circulating through the fluid path 876 along the axis 224. The mating protrusions 570 may cause jetting effects within the fluid path 876 at the low-height regions of the edges of the fins 222 that define the fluid path 876. The mixing, turbulence, and/or jetting caused by the mating protrusions 570 may improve the profile of the thermal boundary layer formed by fluid circulating through the fluid path 876, which may contribute to improved heat transfer efficiency for the fluid heat exchanger 100.

After circulating through the fluid path 876, the fluid may exit the fluid path 876 and enter a peripheral cavity 880 defined by the housing 160 (or defined by the housing body 568) and by the second side 218 of the base plate 214 of the cold plate 110. For clarity, the peripheral cavity 880 is also labeled in FIGS. 6 and 7, which illustrate that the peripheral cavity 880 is open to the fluid outlet 566, allowing the fluid (warmed by passing through the fluid path 876 and other fluid paths defined by the fluid heat exchanger 100) to exit the fluid heat exchanger 100 to be re-cooled and re-circulated through the fluid heat exchanger 100. In this regard, the fluid paths of the fluid heat exchanger 100 defined by the mating protrusions 570, the fins 222 of the cold plate 110, and the second side 218 of the base plate 214 of the cold plate 110 can facilitate circulation of heat transfer fluid from the fluid inlet 564 to the fluid outlet 566.

As noted above, the designation of certain fluid ports of the fluid heat exchanger 100 as fluid inlets (e.g., fluid inlet 564) and fluid outlets (e.g., fluid outlet 566) is arbitrary, and other designations are possible. Accordingly, although at least some examples described herein have focused, in at least some respects, on circulation of fluid from the fluid inlet 564 to the fluid outlet 566, the principles described herein may be implemented to facilitate circulation of fluid from the fluid port referred to herein as fluid outlet 566 to the fluid port referred to herein as the fluid inlet 564.

### V. Other Embodiments

The embodiments of disclosed principles described above generally concern mechanical retention systems, devices, components, and related methods.

Nonetheless, the previous description is provided to enable a person skilled in the art to make or use the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by reference in its entirety for all purposes.

In addition, unless otherwise indicated, numbers expressing quantities, constituents, distances, or other measurements used in the specification and claims are to be understood as optionally being modified by the term “about” or its synonyms. When the terms “about,” “approximately,” “substantially,” or the like are used in conjunction with a stated amount, value, or condition, it may be taken to mean an amount, value or condition that deviates by less than 20%, less than 10%, less than 5%, less than 1%, less than 0.1%, or less than 0.01% of the stated amount, value, or condition. At the very least, and not as an attempt to limit the application of the doctrine of equivalents to the scope of the claims, each numerical parameter should be construed in light of the number of reported significant digits and by applying ordinary rounding techniques.

Those of ordinary skill in the art will appreciate that the exemplary embodiments disclosed herein can be adapted to various configurations and/or uses without departing from the disclosed principles. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of mechanical retention components, devices, and related systems and methods that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

We currently claim:

1. A fluid heat exchanger, comprising:
a cold plate, comprising:
a base plate comprising:
a first side configured to contact an electronic component; and
a second side opposite the first side; and
a plurality of fins extending from the second side, wherein the plurality of fins and the second side of the base plate define a plurality of microchannels extending along a first axis, wherein at least a subset of fins of the plurality of fins defines one or more elongated recesses extending along a second axis that is angularly offset from the first axis; and
a housing comprising a housing body that defines:
a fluid inlet;
a fluid outlet; and
one or more mating protrusions configured to extend into the one or more elongated recesses such that the plurality of microchannels and the housing body form a plurality of fluid paths for circulating a heat transfer fluid along the first axis and from the fluid inlet to the fluid outlet or vice-versa.

2. The fluid heat exchanger of claim 1, wherein the fluid heat exchanger omits an intermediate plate that intervenes between the housing body and the cold plate.

3. The fluid heat exchanger of claim 1, wherein the subset of fins of the cold plate define a central elongated recess.

4. The fluid heat exchanger of claim 3, wherein the housing body comprises one or more partial protrusions configured to partially extend into the central elongated recess when the one or more mating protrusions extend into the one or more elongated recesses.

5. The fluid heat exchanger of claim 1, wherein each of the one or more elongated recesses is defined by a first discontinuous wall, a second discontinuous wall, and a discontinuous base, wherein the first discontinuous wall, the second discontinuous wall, and the discontinuous base are defined by the subset of fins of the plurality of fins, and wherein the first discontinuous wall is non-parallel to the second discontinuous wall.

6. A fluid heat exchanger, comprising:
a cold plate, comprising:
a base comprising:
a first side configured to contact an electronic component; and
a second side opposite the first side; and
a plurality of fins extending from the second side, wherein the plurality of fins and the second side of the base define a plurality of microchannels extending along a first axis, wherein at least a subset of fins of the plurality of fins defines a plurality of elongated recesses extending along a second axis that is angularly offset from the first axis, wherein the plurality of elongated recesses comprises a central elongated recess; and
a housing configured to connect to the cold plate, the housing comprising:
one or more mating protrusions configured to extend into at least some of the plurality of elongated recesses when the housing connects to the cold plate such that the plurality of microchannels and the housing form a plurality of fluid paths for circulating a heat transfer fluid along the first axis; and
a housing body defining a central cavity arranged over the central elongated recess when the housing connects to the cold plate.

7. The fluid heat exchanger of claim 6, wherein the housing omits a mating protrusion configured to extend into the central elongated recess when the housing connects to the cold plate.

8. The fluid heat exchanger of claim 6, wherein the housing comprises one or more partial protrusions configured to partially extend into the central elongated recess when the housing connects to the cold plate.

9. The fluid heat exchanger of claim 6, wherein the housing body defines a fluid inlet, a fluid outlet, and the one or more mating protrusions.

10. The fluid heat exchanger of claim 9, wherein the fluid heat exchanger omits an intermediate plate that intervenes between the housing body and the cold plate.

11. The fluid heat exchanger of claim 6, wherein each of the plurality of elongated recesses is defined by a first discontinuous wall, a second discontinuous wall, and a discontinuous base, wherein the first discontinuous wall, the second discontinuous wall, and the discontinuous base are defined by the subset of fins of the plurality of fins, and wherein the first discontinuous wall is non-parallel to the second discontinuous wall.

12. A cold plate for a fluid heat exchanger, comprising:
a base comprising:
a first side configured to contact an electronic component; and
a second side opposite the first side; and
a plurality of fins extending from the second side, wherein the plurality of fins and the second side of the base define a plurality of microchannels extending along a first axis, wherein:
at least a subset of fins of the plurality of fins defines one or more elongated recesses extending along a second axis that is angularly offset from the first axis,
each of the one or more elongated recesses is defined by a first discontinuous wall, a second discontinuous wall, and a discontinuous base, wherein the first discontinuous wall, the second discontinuous wall, and the discontinuous base are defined by the subset of fins of the plurality of fins, and
for each of the one or more elongated recesses, the first discontinuous wall is non-parallel to the second discontinuous wall.

13. The cold plate of claim 12, wherein, for each of the one or more elongated recesses, the first discontinuous wall and the second discontinuous wall converge toward the discontinuous base.

14. The cold plate of claim 12, wherein the one or more elongated recesses comprise a plurality of elongated recesses.

15. The cold plate of claim 14, wherein at least two elongated recesses of the plurality of elongated recesses comprise different discontinuous base widths.

16. The cold plate of claim 14, wherein at least two sets of adjacent elongated recesses of the plurality of elongated recesses comprise different distances between adjacent discontinuous bases.

17. The cold plate of claim 14, wherein the subset of fins of the plurality of fins defines a plurality of bridges between adjacent elongated recesses of the plurality of elongated recesses.

18. The cold plate of claim 14, wherein at least two elongated recesses of the plurality of elongated recesses comprise different distances from the second side of the base to the discontinuous base.

19. The cold plate of claim 17, wherein at least two of the plurality of bridges comprise different widths.

20. The cold plate of claim 17, wherein a distance from one bridge of the plurality of bridges to the second side of the base is different from another distance from another bridge of the plurality of bridges to the second side of the base.
